(19) United States
(12) Patent Application Publication
(10) Pub. No.: US 2004/0140861 A1
(43) Pub. Date: Jul. 22, 2004

(54) High temperature superconducting mini-filter resonator configuration with low sensitivity to variations in substrate thickness and resonator patterning

(76) Inventor: Robby L. Alvarez, Newark, DE (US)

Correspondence Address: E I DU PONT DE NEMOURS AND COMPANY, LEGAL PATENT RECORDS CENTER, BARLEY MILL PLAZA 25/1128, 4417 LANCASTER PIKE, WILMINGTON, DE, 19805, US

(21) Appl. No.: 10/712,562

(22) Filed: Nov. 13, 2003

Related U.S. Application Data
(60) Provisional application No. 60/426,846, filed on Nov. 15, 2002.

(51) Int. Cl. H03H 7/01; H01B 12/02

(52) U.S. Cl. 333/99 S; 505/210; 333/185

(57) ABSTRACT

High temperature superconductor mini-filters and mini-multiplexers are comprised of improved self-resonant spiral resonators and have very small size, very low cross-talk between adjacent channels and low sensitivity to variations in substrate thickness and resonator patterning.

This application claims the benefit of U.S. Provisional Application No. 60/426,846, filed Nov. 15, 2002, which is incorporated in its entirety as a part hereof for all purposes.

### FIELD OF THE INVENTION

This invention relates to high temperature superconductor mini-filters and mini-multiplexers comprised of improved self-resonant spiral resonators, which have the advantages of very small size, very low cross-talk between adjacent filters and low sensitivity to variations in substrate thickness and resonator patterning.

### BACKGROUND OF THE INVENTION

High temperature superconductor (HTS) materials are generally considered to be those that superconduct at a temperature of 77K or higher. HTS filters have many applications in telecommunication, instrumentation and military equipment. The HTS filters have the advantages of extremely low in-band insertion loss, high off-band rejection and steep skirts due to the extremely low loss in the HTS materials. In the usual design, the HTS mini-filters and mini-multiplexers are comprised of self-resonant spiral resonators that are relatively large in size. In fact, at least one dimension of the resonator is equal to approximately one-half wavelength. For low frequency HTS filters with many poles, a typical design requires a very large substrate area. The substrates of thin film HTS circuits are special single crystal dielectric materials with high cost. The HTS thin film coated substrates are even more costly. In addition, the cooling power, the cooling time, and therefore the cost to cool the HTS filter circuit to operating cryogenic temperature increases with increasing circuit size. Therefore, it is important to reduce the HTS filter size without sacrificing its performance.

One approach for reducing the HTS filter size is to use “lumped circuit” elements such as capacitors and inductors to build the resonators used in the HTS filters. A conventional spiral element inductor, however, has magnetic fields that extend far beyond the inductor and can result in undesirable cross-talk between adjacent circuits. In a lumped circuit filter design, the two ends of a spiral inductor must also be connected to other circuit components such as capacitors. Since one of the two ends of the spiral inductor is located at the center of the spiral, it cannot be directly connected to other components. To make the connection from the center end of the spiral inductor to another component, an air-bridge or multi-layer over-pass must be fabricated on top of the HTS spiral inductor. This is difficult to fabricate and degrades the performance of the filter. Lumped capacitors in a filter may be introduced in two different ways. One is to use a “drop-in” capacitor that usually has unacceptably large tolerance. The other is to use a planar interdigital capacitor that requires a very narrow gap between two electrodes. The high radio frequency (“RF”) voltage across the electrodes may cause arcing.

U.S. Pat. No. 6,108,569 and U.S. Pat. No. 6,370,404 disclose the use of a self-resonant spiral resonator to reduce the size of HTS filters and solve cross-talk and connection problems, wherein the spiral resonator comprises a high temperature superconductor line oriented in a spiral fashion such that adjacent lines of the spiral resonator are spaced from each other by a gap distance which is less than the line width, and wherein a central opening in the resonator has a dimension approximately equal to that of the gap distance in each dimension.

An embodiment of the self-resonant spiral resonator of U.S. Pat. No. 6,108,569 and U.S. Pat. No. 6,370,404 is shown, for example, in FIG. 1. The resonator comprises a high temperature superconductor line 1 oriented in a rectangular spiral fashion. The resonator can have different shapes, such as rectangular, rectangular with rounded corners, polygonal with more than four sides and circular. The adjacent superconductor lines 1 of line width (“w”) that form the spiral of FIG. 1 are spaced from each other by a gap 2 of distance (“d”) which is less than the width of the line, i.e., d<w. A central opening 3 has dimensions approximately equal to that of the gap distance d. A conductive tuning pad may be placed in the central opening to fine tune the frequency of the spiral resonator. This tuning pad can be a high temperature superconductor.

Although it is important to try to reduce filter size, it is also important that filter performance not be adversely affected in the effort. Filter performance is highly dependent on the frequencies of the resonators of which the filter is comprised. In turn, variations in circuit parameters such as substrate thickness, dielectric constant, resonator patterning, and HTS material properties affect the frequency of the resonators. It is both difficult and costly to try to control these parameters precisely. There is consequently a need for a resonator that is less sensitive to these parameters in order to obtain high filter performance, with high yield in mass production and at reasonable cost, and yet is smaller in size. The availability of a smaller resonator enables making a filter of reduced size.

Despite the proposals as made in the art for reducing filter size, there remains a need for a self-resonant spiral resonator that can be used in the fabrication of mini-filters and mini-multiplexers wherein the spiral resonator is not only less sensitive to varying circuit parameters but is smaller in size.

### SUMMARY OF THE INVENTION

One embodiment of this invention is a self-resonant spiral resonator that includes a high temperature superconductor line oriented in a spiral fashion such that adjacent lines of the spiral resonator are spaced from each other by a gap distance which is less than the line width of the high temperature superconductor line and so as to provide a central opening within the spiral resonator,

wherein the gap distance is varied by utilizing at least two different gap distances such that the gap distance in an outer portion of the spiral resonator is greater than the gap distance in an inner portion of the spiral resonator, and

wherein the dimensions of the central opening are approximately equal to the gap distance in an inner portion of the spiral resonator.

A further embodiment of this invention is a self-resonant spiral resonator including a high temperature superconductor line oriented in a spiral fashion wherein adjacent portions of the line are spaced from each other by a gap, the width of the gap is less than the width of the adjacent portions of the line, the width of the gap is not constant along the length of the gap and a central opening is formed by the spiral superconductor line.

Another embodiment of this invention is a HTS mini-filter containing at least two self-resonant spiral resonators as variously described above.

A further embodiment of this invention is a high temperature superconductor mini-multiplexer containing at least two mini-filters, each mini-filter having a frequency band which is different from and does not overlap with the frequency bands of each other mini-filter; wherein each of the at least two mini-filters contains at least two self-resonant spiral resonators as variously described above.

A further embodiment of this invention is a cryogenic receiver front end, or a tower-mounted telecommunications system, that includes at least one mini-filter or mini-multiplexer as described above.

### BRIEF DESCRIPTION OF THE DRAWINGS

FIG. 1 shows a prior art rectangular self-resonant spiral resonator with a uniform gap distance d less than the HTS line width w.

FIG. 2 show a rectangular self-resonant spiral resonator of the present invention with two different gap distances d₁ and d₂, both less than the HTS line width w.

FIGS. 3A-3E show the configurations of the rectangular self-resonant spiral resonators with uniform gaps used in Comparative Experiments A-E.

FIG. 4 shows a plot of resonant frequency versus substrate thickness for each of the self-resonant spiral resonators of Comparative Experiments A-E.

FIGS. 5A-5E show the configurations of the rectangular self-resonant spiral resonators with two different gap distances d₁ and d₂ used in Examples 1-5, wherein d₁ and d₂ are each the gap distance over approximately half the length of the spiral of each spiral resonator.

FIG. 6 shows a plot of resonant frequency versus substrate thickness for each of the self-resonant spiral resonators of Examples 1-5.

FIGS. 7A and 7B show configurations of the rectangular self-resonant spiral resonators with two different gap distances d₁ and d₂ used in Examples 6 and 7.

FIG. 8 shows a plot of resonant frequency versus HTS line width for the self-resonant spiral resonators of Example 8 and Comparative Experiment F.

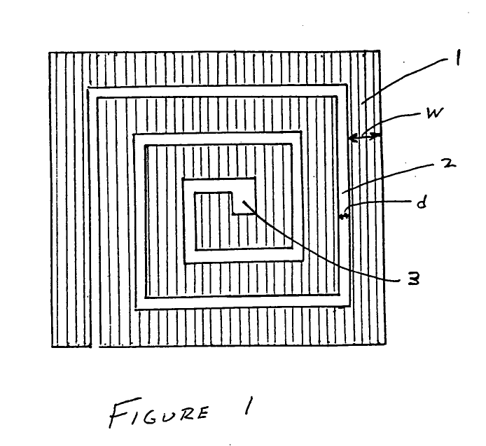

### DETAILED DESCRIPTION OF THE PREFERRED EMBODIMENTS

The present invention provides a smaller self-resonant spiral resonator with low sensitivity to variations in substrate thickness and resonator patterning. This self-resonant spiral resonator comprises a high temperature superconductor line oriented in a spiral fashion such that adjacent lines of the spiral resonator are spaced from each other by a gap distance d which is less than the superconductor line width w and so as to provide a central opening within the spiral resonator. As a spiral is the path of a point in a plane that is moving around a central point while continuously receding from or approaching the central point, the adjacent lines of the spiral resonator may also be thought of as adjacent portions of the continuous superconductor line.

In the spiral resonator of this invention, the gap distance is varied by utilizing at least two different gap distances such that the gap distance in the outer portion of the spiral resonator is greater than the gap distance in the inner portion of the spiral resonator, and wherein the dimensions of the central opening are approximately equal to the gap distance in the inner portion of the spiral resonator. The outer portion of the spiral resonator begins at the end of the superconductor line farthest from the center of the spiral, and the inner portion of the spiral resonator ends at the end of the superconductor line at the center of the spiral. Mini-filters and mini-multiplexers comprised of such self-resonant spiral resonators have the advantage of very small size and low cross-talk between adjacent filters along with the low sensitivity to variations in substrate thickness and resonator patterning.

The spiral resonator of this invention is preferably self-resonant. Self-resonance occurs when the operating frequency is equal to the self-resonance frequency, fₛ, fₛ being known from the equation

fₛ=1/{2π[LCₚ]^{1/2}},

in which L is the inductance of the spiral, and Cₚ is the parasitic capacitance between adjacent turns.

In the design of an HTS filter using spiral resonators, it is desirable to reduce the size of the filter. This requires that the open area in the center of the spiral as well as the gap distance d between the superconductor lines be minimized. These adjustments not only reduce the size of the spiral resonator, but also eliminate the need for adjusting capacitance and the need for a center connection. Moreover, these adjustments also confine most of the electromagnetic fields beneath the spiral resonator and therefore solve the cross-talk problem caused by far reaching magnetic fields in the lumped conductors of the prior art.

It has now been found that varying the gap distance by utilizing at least two different gap distances such that the gap distance in an outer portion of the spiral resonator is greater than the gap distance in an inner portion of the spiral resonator, and wherein the dimensions of the central opening are approximately equal to the gap distance in the inner portion of the spiral resonator, results in a very small spiral resonator with low sensitivity of the resonant frequency (alternatively referred to as the “center frequency”) of the spiral resonator to variations in substrate thickness and resonator patterning. Preferably, the gap distance d for each gap distance is less than w/2.

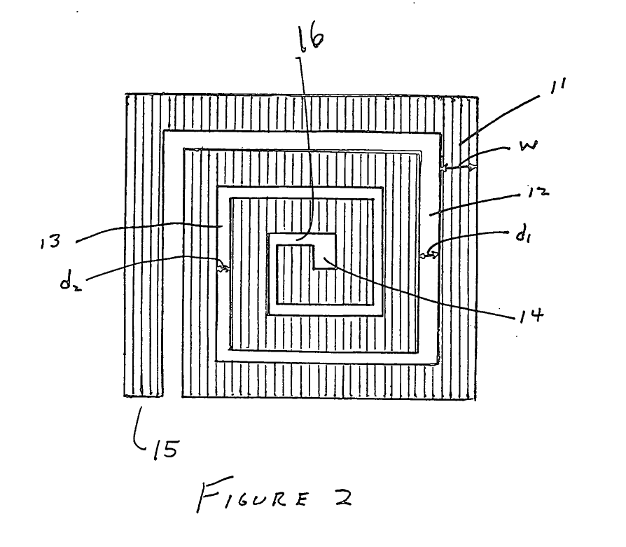

For purposes of illustration, spiral resonators characterized by two gap distances will be shown and discussed, but 3, 4 or more different gap distances can be used in a single spiral resonator. FIG. 2 shows an embodiment of the self-resonant spiral resonator of this invention with two gap distances. The self-resonant spiral resonators comprise a high temperature superconductor line 11 oriented in a rectangular spiral fashion. The self-resonant spiral resonators can have different shapes, including rectangular, rectangular with rounded corners, polygonal with more than four sides, and circular (which need not be a perfect circle).

The adjacent superconductor lines 11 of line width w that form the spiral of FIG. 2 are spaced from each other by a gap 12 of distance d₁ in an outer portion of the spiral resonator and by a gap 13 of distance d₂ in an inner portion of the spiral resonator such that d₂<d₁<w. An outer portion of the spiral resonator is the portion that begins at the point 15 farthest from the center of the superconductor line, and an inner portion of the spiral resonator is the portion that terminates at the point 16 nearest to the center of the superconductor line in the central opening 14. Central opening 14 has dimensions approximately equal to that of the gap distance d₂, although its configuration may vary in alternative embodiments. A superconductive tuning pad may be placed in the central opening to fine tune the frequency of the spiral resonator.

For the embodiment shown in FIG. 2, d₁ and d₂ are each the gap distance for about 50% of the length of the spiral, and d₂<d₁. Such a spiral resonator with a gap distance of d₂ over the inner 50% of the length of the spiral and a gap distance of d₁ over the outer 50% of the length of the spiral may be described as a 50% d₂/50% d₁ spiral resonator. Preferably, when two gap distances are used, d₂ is the gap distance for about 25% to about 75% of the length of the spiral and d₁ is the gap distance for the remaining portion of the length of the spiral, i.e., for about 25% to about 75% of the length of the spiral. In such case, the spiral resonator may be about a 25% d₂/75% dl resonator, about a 75% d₂/25% d₁ resonator, or may have values for each of d₁ and d₂ between 25% and 75%. More preferably, the spiral resonator is about a 50% d₂/50% d₁ resonator. In all such cases, all portions (expressed as percentages) of the total length of the spiral over which a different gap distance exists will add up to 100%. Preferably, d₁ and d₂ are both less then w/2.

In alternative embodiments, however, whether two or more than two different gap distances are used, each gap distance d may be for a length of the spiral resonator that is about 20% or more, is about 30% or more, or is about 40% or more, and yet is about 80% or less, is about 70% or less or is about 60% or less of the length of the spiral resonator. In all such cases, all portions (expressed as percentages) of the total length of the spiral over which a different gap distance exists will add up to 100%. Preferably, each gap distance is less than w/2.

A mini-filter according to this invention contains the self-resonant spiral resonators as described above, and therefore has low sensitivity to variations in substrate thickness and resonator patterning as well as a smaller size. Preferably, all the self-resonant spiral resonators in a mini-filter have an identical shape, i.e., rectangular, rectangular with rounded corners, polygonal with more than four sides, or circular (which need not be a perfect circle). Each self-resonant spiral resonator is, however, independently characterized as described above in terms of gap distance.

The input and output coupling circuits of a mini-filter according to this invention may have a configuration exemplified by the following:

1. a parallel lines configuration which involves a transmission line with a first end thereof connected to an input connector of the filter via a gold pad on top of the line, and a second end thereof extended to be close by and in parallel with the spiral line of the first spiral resonator (for the input circuit) or the last spiral resonator (for the output circuit) to provide the input or output couplings for the filter; or

2. an inserted line configuration which involves a transmission line with a first end thereof connected to an input connector of the filter via a gold pad on top of the line, and a second end thereof extended to be inserted into the split spiral line of the first spiral resonator (for the input circuit) or the last spiral resonator (for the output circuit) to provide the input or output couplings for the filter.

The inter-resonator couplings between adjacent spiral resonators in a mini-filter according to this invention are provided by the overlapping of the electromagnetic fields at the edges of the adjacent spiral resonators. In addition, HTS lines can be provided between the spiral resonators to increase coupling and adjust the frequency of the mini-filter.

The mini-filters of this invention can be used to build mini-multiplexers, which will contain the self-resonant spiral resonators of this invention, as described above, and will therefore have low sensitivity to variations in substrate thickness and resonator patterning as well as a smaller size. A mini-multiplexer contains at least two channels with two mini-filters having slightly different non-overlapping frequency bands, an input distribution network, and an output port for each channel. The two or more mini-filters of which a mini-multiplexer is fabricated can each be on a separate substrate or they can all be on a single substrate.

The mini-filters and mini-multiplexers of this invention can be in the microstrip line form with one substrate and one ground plane; they also can be in the strip line form with a substrate, a superstrate and two ground planes.

For example, when a self-resonant spiral resonator of this invention is incorporated into a high temperature superconductor mini-filter, the mini-filter may include a substrate having a front side and a back side; at least two self-resonant spiral resonators as described herein in intimate contact with or disposed on the front side of the substrate; at least one inter-resonator coupling; an input coupling circuit comprising a transmission line with a first end thereof connected to an input connector of the filter and a second end thereof coupled to a first one of the at least two self-resonant spiral resonators; an output coupling circuit comprising a transmission line with a first end thereof connected to an output connector of the filter and a second end thereof coupled to a last one of the at least two self-resonant spiral resonators; a blank high temperature superconductor film disposed on the back side of the substrate as a ground plane; and a conductive film disposed on the blank high temperature superconductor film. The conductive film may be a gold film, and may serves as a contact to a case of the mini-filter. The mini-filter may further include a superstrate having a front side and a back side, wherein the front side of the superstrate is positioned in intimate contact with the at least two resonators disposed on the front side of the substrate; a second blank high temperature superconductor film disposed on the back side of the superstrate as a ground plane; and a second conductive film disposed on the surface of the second high temperature superconductor film. The conductive film and the second conductive film may be gold films, and may serve as contacts to a case of the mini-filter.

In a further embodiment, when a self-resonant spiral resonator of this invention is incorporated into a high temperature superconductor mini-multiplexer, the mini-multiplexer may include (a) at least two mini-filters as described above, each mini-filter having a frequency band that is different from and does not overlap with the frequency bands of each other mini-filter; (b) a distribution network with one common port as an input for the mini-multiplexer and multiple distributing ports, wherein a respective distributing port is connected to an input of a corresponding mini-filter; and (c) a multiple of output lines, wherein a respective output line is connected to an output of a corresponding mini-filter.

In all of the embodiments described herein, a variety of high temperature superconductor materials may be use, but it is preferred that the high temperature superconductor is selected from the group consisting of YBa₂Cu₃O₇, Tl₂Ba₂CaCu₂O₈, TlBa₂Ca₂Cu₃O₉, (TlPb)Sr₂CaCu₂O₇ and (TlPb)Sr₂Ca₂Cu₃O₉. It is also preferred that the substrate and superstrate are independently selected from the group consisting of LaAlO₃, MgO, LiNbO₃, sapphire and quartz. It is well known that the presence of a buffer or intermediate layer of an oxide on the substrate before the deposition of the superconductor can be useful in promoting growth of the superconductor film. Therefore, as used herein, “intimate contact with the front side of the substrate” means direct intimate contact with the front side of the substrate as well as intimate contact with an intermediate or buffer layer on the front side of the substrate.

The following examples will illustrate, but do not limit the scope of, this invention.

All examples and comparative experiments were carried out using Sonnet EM software, obtained from Sonnet Software, Inc., Liverpool, N.Y. 13088, to simulate the performance of a spiral resonator or a mini-filter. The following model was used. There was a substrate of given thickness and dielectric constant and having a front side and a back side. The spiral resonator was in intimate contact with the front side of the substrate. A ground plane, which in practice would be a blank, i.e., continuous, superconductor film, was on the back side of the substrate. The grounded top cover and side walls of the circuit were all sufficiently far from the spiral resonator so as to have negligible effect.

### EXAMPLES OF THE INVENTION COMPARATIVE EXPERIMENTS A-E

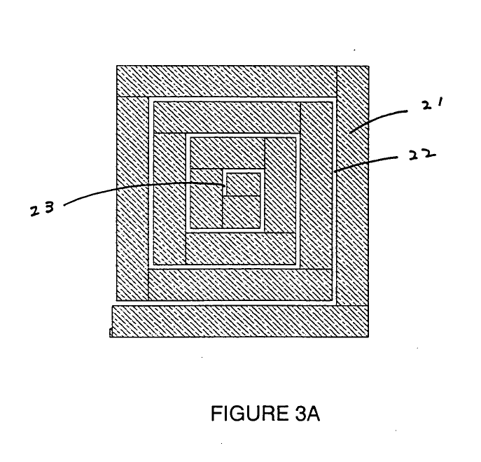

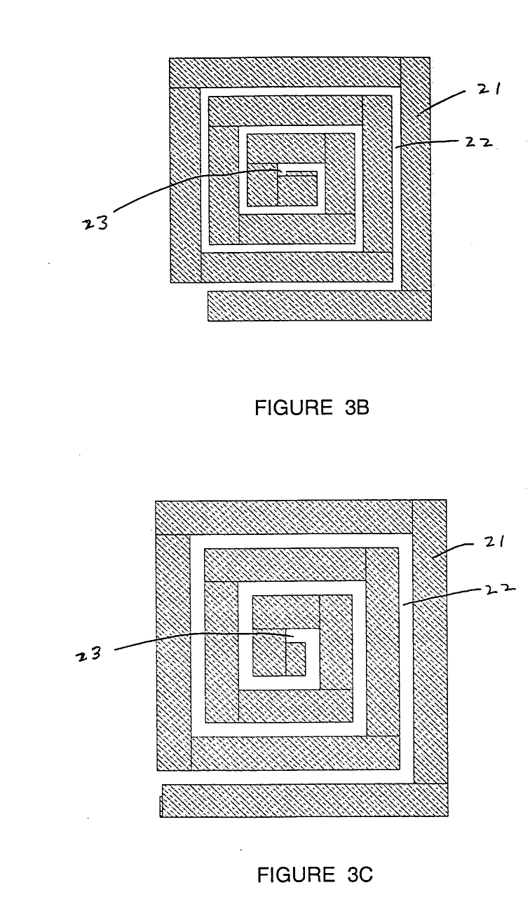

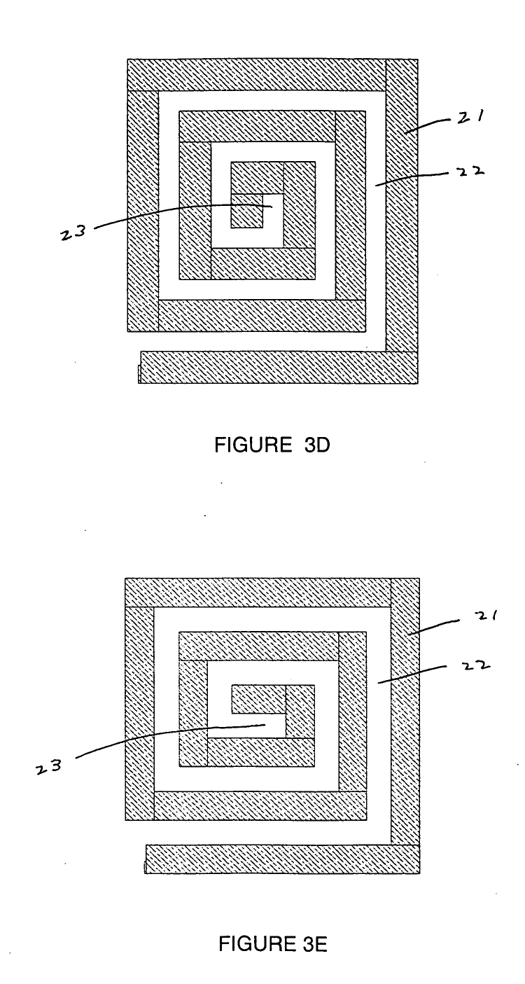

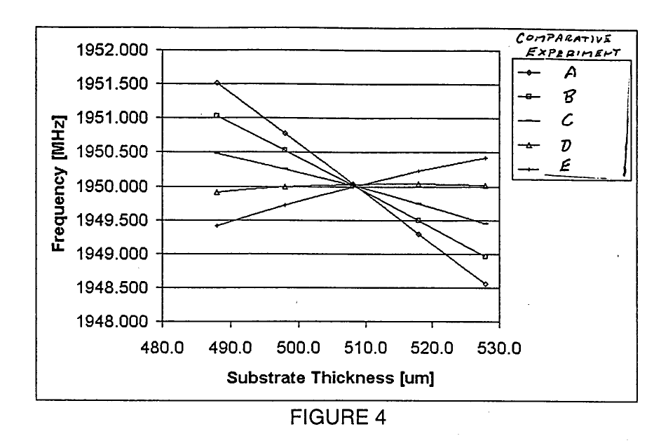

The frequency dependence with the variation in substrate thickness of prior art self-resonant spiral resonators with uniform line width w and uniform gap distance d, wherein d<w, was demonstrated for the five self-resonant spiral resonator configurations shown in FIGS. 3A-3E using Sonnet EM software to simulate performance. Because the structural components such as the substrate and the HTS superconductor of the five spiral resonators are the same (the only difference being the magnitude of the gap distance) the same reference numerals are used to denote the same structural components. As seen in FIGS. 3A-3E, the self-resonant spiral resonator comprises a high temperature superconductor line, numeral 21, oriented in a rectangular spiral fashion. The adjacent superconductor lines, numeral 21, of line width w that form the spirals of FIGS. 3A-3E are spaced from each other by a gap, numeral 22, of distance d and d<w. Numeral 23 is the central opening with dimensions approximately equal to d. In each spiral resonator, the superconductor line width w=308 μm. The gap distances are 44, 88, 132, 198 and 264 μm for Comparative Experiments A-E, respectively, as shown in FIGS. 3A-3E. The gap distances as a fraction of the line width are w/7, 2w/7, 3w/7, 9w/14 and 6w/7, respectively. The dielectric constant of the substrate was 24 and the resistivity of the superconductor line was 0. All five spiral resonators were designed to resonate at 1950 MHz with a substrate thickness of 508 μm. The resonant frequency of each of the five spiral resonators was then determined as the substrate thickness was varied from about 488 μm to about 528 μm. The results for all five spiral resonators are shown plotted in FIG. 4. The spiral resonator of Comparative Experiment D with a uniform gap distance of 198 μm, which is 9w/14, shows the least sensitivity to variations in substrate thickness.

### EXAMPLES 1-5

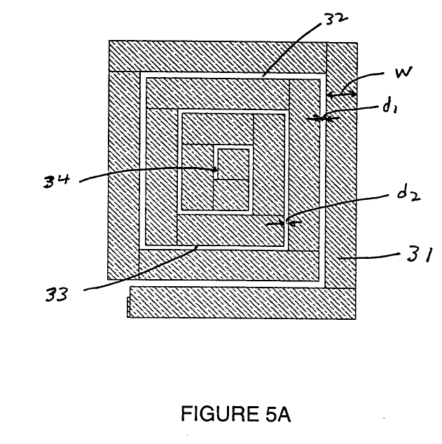

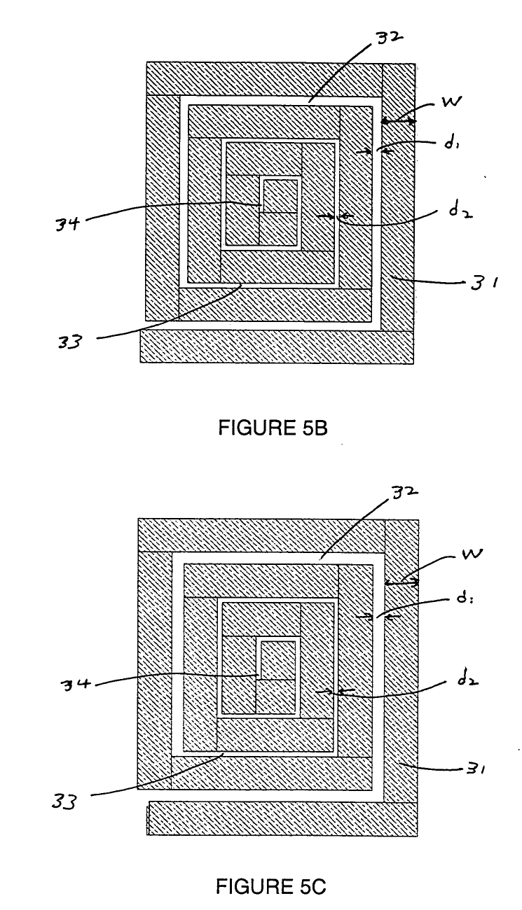

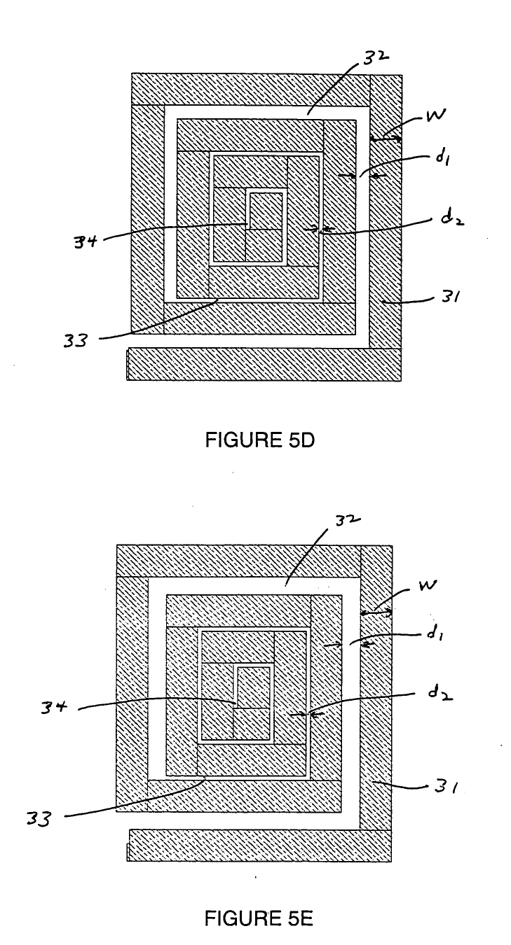

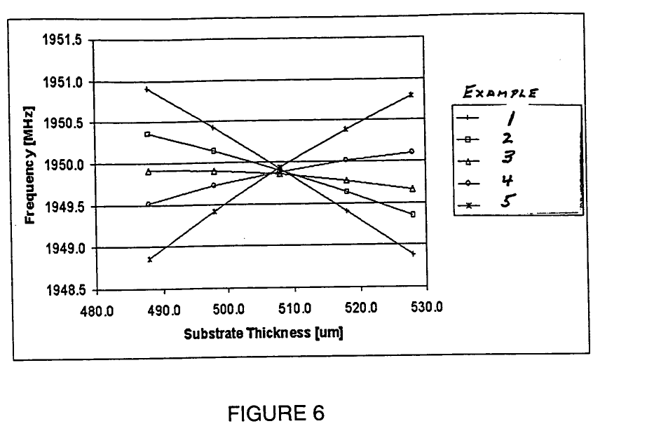

The frequency dependence with the variation in substrate thickness of self-resonant spiral resonators of this invention with uniform line width w and a varying gap distance, was demonstrated for the five self-resonant spiral resonator configurations shown in FIGS. 5A-5E using Sonnet EM software to simulate performance. These spiral resonators all have two different gap distances d₁ and d₂. Because the structural components such as the substrate and the HTS superconductor of the five spiral resonators are the same (the only difference being the magnitude of the gap distance d₁) the same reference numerals are used to denote the same structural components. As seen in FIGS. 5A-5E, the self-resonant spiral resonator comprises a high temperature superconductor line, numeral 31, oriented in a rectangular spiral fashion. The adjacent superconductor lines, numeral 31, of line width w that form the spirals of FIGS. 5A-5E are spaced from each other by a gap, numeral 32, of distance d₁ over the outer portion of the spiral resonator and a gap, numeral 33, of distance d₂ over the inner portion of the spiral resonator, and d₂<d₁<w. d₁ and d₂ are each the gap distance for approximately 50% of the length of the spiral of each spiral resonator, i.e., about 50% d₂ and about 50% d₁ over the length of the spiral. Numeral 34 is the central opening with dimensions approximately equal to d₂. In each spiral resonator, the superconductor line width w=308 μm. The gap distance d₂ for the inner portion of all five spiral resonators is 44 μm, i.e., the gap distance d₂ as a fraction of the line width is w/7. The gap distances d₁ for the outer portion of the five spiral resonators are 66, 88, 110, 132 and 176 μm for Examples 1-5, respectively, as shown in FIGS. 5A-5E. The gap distances d₁ as a fraction of the line width are 3w/14, 2w/7, 5w/14, 3w/7 and 4w/7, respectively. The dielectric constant of the substrate was 24 and the resistivity of the superconductor line was 0. All five spiral resonators were designed to resonate at approximately 1950 MHz with a substrate thickness of 508 μm. The resonant frequency of each of the five spiral resonators was then determined as the substrate thickness was varied from about 488 μm to about 528 μm. The results for all five spiral resonators are shown plotted in FIG. 6. The spiral resonator of Example 3 with d₂=44 μm and d₁=110 μm, i.e. with d₁=w/7 and d₂=5w/14 so that both are less than w/2, shows the least sensitivity to variations in substrate thickness. This degree of insensitivity to substrate thickness variation is about what was obtained with the larger spiral resonator of Comparative Experiment D with a uniform gap distance of 198 μm.

These results demonstrate that to produce a self-resonant spiral resonator with a given low sensitivity to substrate thickness variations, a self-resonant spiral resonator of this invention with at least two different gap distances is smaller in size than a self-resonant spiral resonator with a uniform gap distance. The availability of the smaller spiral resonator of this invention enables making a filter of reduced size.

### EXAMPLES 6-7

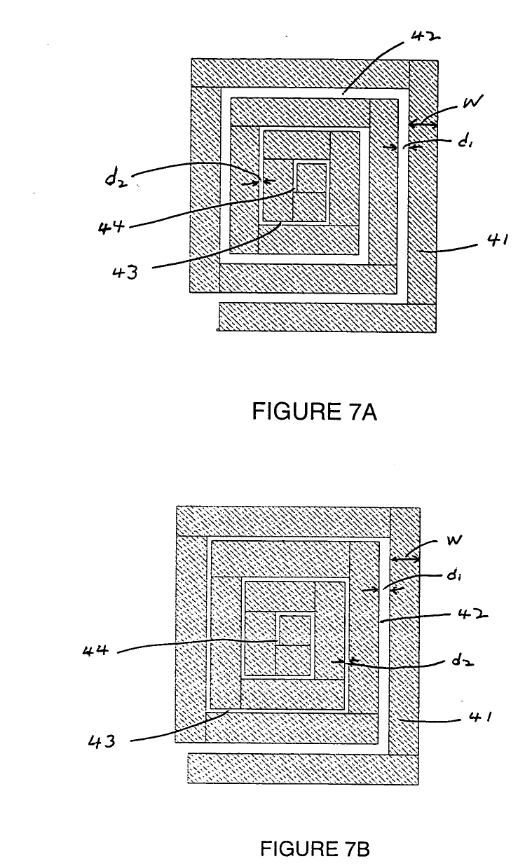

To demonstrate the differences in frequency dependence with the variation in substrate thickness of self-resonant spiral resonators of this invention with uniform line width w and a varying gap distance, the two self-resonant spiral resonator configurations shown in FIGS. 7A and 7B were used to simulate performance using Sonnet EM software. These spiral resonators also have two different gap distances d₁ and d₂ as did the spiral resonators of the previous Examples with d₂<d₁<w. As in Example 3, for the spiral resonators of Examples 6 and 7, the superconductor line width w=308 μm, the gap distance d₂ for the inner portion of the spiral resonators is 44 μm and the gap distance d₁ for the outer portion of the spiral resonators is 110 μm. However, for Example 6 (FIG. 7A), d₂ is the gap distance for approximately 30% of the length of the spiral of the spiral resonator and d₁ is the gap distance for approximately 70% of the length of the spiral of the spiral resonator, i.e., about 30% d₂-about 70% d₁ over the length of the spiral. For Example 7 (FIG. 7B), d₂ is the gap distance for approximately 75% of the length of the spiral of the spiral resonator and d₁ is the gap distance for approximately 25% of the length of the spiral of the spiral resonator, i.e., about 75% d₂-about 25% d₁ over the length of the spiral. Because the structural components such as the substrate and the HTS superconductor of both spiral resonators are the same (the only difference being the proportions of the spiral with the different gap distances) the same reference numerals are used to denote the same structural components. As seen in FIGS. 7A and 7B, the self-resonant spiral resonator comprises a high temperature superconductor line, numeral 41, oriented in a rectangular spiral fashion. The adjacent superconductor lines, numeral 41, of line width w that form the spirals of FIGS. 7A and 7B are spaced from each other by a gap, numeral 42, of distance d₁ over the outer portion of the spiral resonator and a gap, numeral 43, of distance d₂ over the inner portion of the spiral resonator. Numeral 44 is the central opening with dimensions approximately equal to d₂. The dielectric constant of the substrate was 24 and the resistivity of the superconductor line was 0. Both resonators were designed to resonate at approximately 1950 MHz with a substrate thickness of 508 μm. The resonant frequency of each of the two spiral resonators was then determined as the substrate thickness was varied from about 488 μm to about 528 μm. The results for these two spiral resonators as well as that for Example 3 are shown in Table 1 as the percent change in frequency per micron change in substrate thickness.

TABLE I

| | |
|---|---|
| Inner-Outer Gap Percentage | % Change in Frequency |
| (44 μm inner gap; | Per Micron Change |
| 110 μm outer gap) | in Substrate Thickness |

| | | |
|---|---|---|
| Example 6 | 30-70 | 0.0007 |
| Example 3 | 50-50 | 0.0003 |
| Example 7 | 75-25 | 0.0012 |

The spiral resonator of Example 3 shows the least insensitivity to substrate thickness variation.

This demonstrates that to produce a self-resonant spiral resonator of this invention with low sensitivity to substrate thickness variations, it is more preferred to have d₁ and d₂ each be the gap distance for about 50% of the length of the spiral, i.e., for the spiral resonator to be about 50% d₂-50% d₁, with d₁ and d₂ both less then w/2.

### EXAMPLE 8

### Comparative Experiment F

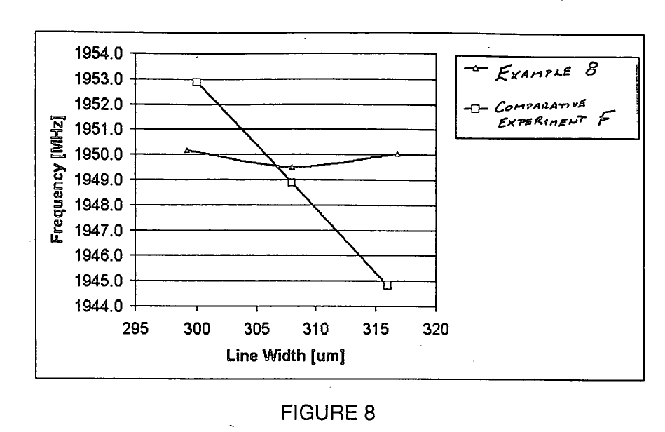

In order to demonstrate the advantages of the spiral resonators of this invention with regard to sensitivity to variations in line width and gap width as would occur by over or under etching during the photo-patterning preparation of the spiral resonator, the spiral resonator described in Example 3 was used for Example 8 and the spiral resonator described in Comparative Experiment D was used for Comparative Experiment F. These spiral resonators were used to simulate performance using Sonnet EM software. They were chosen since they exhibited similar low sensitivity to the variation in substrate thickness. Both were designed with a resonant frequency of about 1950 MHz with a line width of 308 μm. The resonant frequency of the two spiral resonators was then determined as the line width was varied from 300 μm to 316 μm. In order to be consistent with the variations in line width and gap width that would occur during the photo-patterning, as the line width was varied, the sum of the line width and the gap distance was kept constant. That is, as the line width was decreased by an amount δ, the gap distance was increased by an amount δ and as the line width was increased by an amount δ, the gap distance was decreased by an amount δ. The variation in resonant frequency with variation in line width is shown in FIG. 8 for the resonators of Example 8 and Comparative Experiment F. The resonant frequency of the smaller resonator of Example 8 varied by about 0.5 MHz over the range of line width. Over the same line width range, the resonant frequency of the resonator of Comparative Experiment F varied by about 8 MHz, a factor of 16 higher than that of the resonator of Example 8.

This comparison shows the advantage of the spiral resonator of this invention provides with respect to insensitivity to variations in resonator patterning.

What is claimed is:

1. A self-resonant spiral resonator comprising a high temperature superconductor line oriented in a spiral fashion such that adjacent lines of the spiral resonator are spaced from each other by a gap distance that is less than the line width of the high temperature superconductor line and so as to provide a central opening within the spiral resonator,
wherein the gap distance is varied by utilizing at least two different gap distances such that the gap distance in an outer portion of the spiral resonator is greater than the gap distance in an inner portion of the spiral resonator, and
wherein the dimensions of the central opening are approximately equal to the gap distance in an inner portion of the spiral resonator.

2. The self-resonant spiral resonator of claim 1 wherein the self-resonant spiral resonator has a shape selected from the group consisting of rectangular, rectangular with rounded corners, polygonal with more than four sides and circular.

3. The self-resonant spiral resonator of claim 1 further comprising a conductive tuning pad disposed in the central opening of the self-resonant spiral resonator.

4. The self-resonant spiral resonator of claim 1 wherein the high temperature superconductor used to form the high temperature superconductor line is selected from the group consisting of YBa₂Cu₃O₇, Tl₂Ba₂CaCu₂O₈, TlBa₂Ca₂Cu₃O₉, (TlPb)Sr₂CaCu₂O₇ and (TlPb)Sr₂Ca₂Cu₃O₉.

5. The self-resonant spiral resonator of claim 1 wherein the self-resonant spiral resonator is on a substrate selected from the group consisting of LaAlO₃, MgO, LiNbO₃, sapphire and quartz.

6. The self-resonant spiral resonator of claim 1 wherein the gap distance is varied by utilizing two different gap distances d₁ and d₂ such that d₁ is the gap distance over an outer portion of the spiral resonator and d₂ is the gap distance over an inner portion of the spiral resonator; and
wherein the gap distance d₁ is the gap distance for about 25% to about 75% of the length of the spiral of the spiral resonator, and the gap distance d₂ is the gap distance over the remaining portion of the length of the spiral of the spiral resonator.

7. The self-resonant spiral resonator of claim 7 wherein the gap distance d₁ is the gap distance for about 50% of the length of the spiral of the spiral resonator, and the gap distance d₂ is the gap for about 50% of the length of the spiral of the spiral resonator.

8. The self-resonant spiral resonator of claim 1 wherein the gap distance is varied by utilizing two different gap distances d₁ and d₂ such that d₁ is the gap distance over an outer portion of the spiral resonator and d₂ is the gap distance over an inner portion of the spiral resonator; and
wherein the gap distance d₁ and the gap distance d₂ are each less than half of the line width of the high temperature super conductor line.

9. The self-resonant spiral resonator of claim 1 wherein the gap distance is varied by utilizing at least three different gap distances.

10. The self-resonant spiral resonator of claim 9 wherein each gap distance is less than half of the line width of the high temperature super conductor line.

11. A high temperature superconductor mini-filter comprising at least two self-resonant spiral resonators wherein each of the self-resonant spiral resonators is independently a self-resonant spiral resonator according to claims 1, 6, 8, 9 and 10.

12. The high temperature superconductor mini-filter of claim 11 further comprising
(a) a substrate having a front side and a back side wherein each self-resonant spiral resonator is disposed on the front side of the substrate;
(b) at least one inter-resonator coupling;
(c) an input coupling circuit comprising a transmission line with a first end thereof connected to an input connector of the filter and a second end thereof coupled to a first one of the self-resonant spiral resonators;
(d) an output coupling circuit comprising a transmission line with a first end thereof connected to an output connector of the filter and a second end thereof coupled to a last one of the self-resonant spiral resonators;
(e) a blank high temperature superconductor film disposed on the back side of the substrate as a ground plane; and
(f) a conductive film disposed on the blank high temperature superconductor film.

13. The high temperature superconductor mini-filter of claim 12 wherein the conductive film is a gold film.

14. The high temperature superconductor mini-filter of claim 12 wherein the conductive film serves as a contact to a case of the mini-filter.

15. The high temperature superconductor mini-filter of claim 12 further comprising
(g) a superstrate having a front side and a back side, wherein the front side of the superstrate is positioned in intimate contact with the self-resonant spiral resonators disposed on the front side of the substrate;
(h) a second blank high temperature superconductor film disposed on the back side of the superstrate as a ground plane; and
(i) a second conductive film disposed on the surface of the second high temperature superconductor film.

16. The high temperature superconductor mini-filter of claim 15 wherein the conductive film and the second conductive film are gold films.

17. The high temperature superconductor mini-filter of claim 15 wherein the conductive film and the second conductive film serve as contacts to a case of the mini-filter.

18. A high temperature superconductor mini-multiplexer comprising at least two mini-filters,
wherein each mini-filter has a frequency band that is different from and does not overlap with the frequency band of each other mini-filter;
wherein each mini-filter comprises at least two self-resonant spiral resonators; and
wherein each of the self-resonant spiral resonators in each of the mini-filters is independently a self-resonant spiral resonator according to claims 1, 6, 8, 9 and 10.

19. The high temperature superconductor mini-multiplexer of claim 18 further comprising
(a) a distribution network with one common port as an input for the mini-multiplexer and multiple distributing ports, wherein a respective distributing port is connected to an input of a corresponding mini-filter; and
(b) a multiple of output lines, wherein a respective output line is connected to an output of a corresponding mini-filter.

20. A cryogenic receiver front end comprising at least one mini-filter according to claim 11.
